(19) United States
(12) Patent Application Publication
(10) Pub. No.: US 2008/0308922 A1
(43) Pub. Date: Dec. 18, 2008

(54) METHOD FOR PACKAGING SEMICONDUCTORS AT A WAFER LEVEL

(76) Inventors: Yiwen Zhang, Woburn, MA (US); Robert B. Hallock, Newton, NH (US); Michael G. Adlerstein, Wellesley, MA (US); Thomas E. Kazior, Sudbury, MA (US); Susan C. Trulli, Lexington, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 11/762,924

(22) Filed: Jun. 14, 2007

(51) Int. Cl. H01L 23/48; H01L 21/00

(52) U.S. Cl. 257/690; 438/107; 257/E23.01; 257/E23.116

(57) ABSTRACT

A method for packaging a plurality of semiconductor devices formed in a surface portion of a semiconductor wafer. The method includes: lithographically forming in a material disposed on the surface portion of the semiconductor wafer device-exposing openings to exposed the devices and electrical contacts pads openings to expose electrical contact pads for devices; mounting a rigid dielectric layer over the formed material, such rigid material being suspended over the device exposing openings in the material and over the electrical contacts pads openings in the material; and forming electrical contact pad openings in portions of the rigid dielectric layer disposed over electrical contact pads of the devices with other portions of the rigid dielectric layer remaining suspended over the device exposing openings in the material.

### TECHNICAL FIELD

This invention relates generally to methods for packaging (i.e., encapsulating) semiconductors and more particularly to methods for packaging semiconductors at a wafer level (i.e., wafer-level packaging).

### BACKGROUND

As is known in the art, traditionally in the microelectronics industry, electrical devices are fabricated on wafers and then diced into individual chips. The bare chips would then get assembled with other components into a package for environmental and mechanical protection. In commercial applications, the chips were generally assembled into plastic packages. In military applications, where electronics are generally exposed to harsher environments, the parts are generally housed in a hermetic module. Such packages or modules would then be further assembled unto circuit boards and systems. However, as electronic systems advance, there is a need to increase functionality while decreasing the size and cost of components and sub-systems.

One way to reduce size and cost is to create packages at the wafer level and then subsequently dicing the wafer into individual packaged semiconductors (i.e., wafer-level packaging). Many methods have been suggested to create wafer-level packages. One method, call wafer bonding, is to bond a wafer with pre-formed cavities over the device wafer. The bonding can be achieved through thermal bonding, adhesive or solder bonding, see for example, Rainer Pelzer, Herwig Kirchberger, Paul Kettner, “Wafer-to Wafer Bonding Techniques: From MEMS Packaging to IC Integration Applications”, 6^{th} IEEE International Conference on Electronic Packaging Technology 2005 and A. Jourdain, P. De Moor, S. Pamidighantam, H. A. C. Tilmans, “Investigation of the Hermeticity of BCB-Sealed Cavities For Housing RF-MEMS Devices”, IEEE Electronic Article, 2002

However, this method introduces a lot of complexity and issues into the process. Thermal bonding is generally achieved at very high temperatures, in excess of 400 C. Adhesive bonding can be achieved at lower temperature, but adhesive outgassing is a concern. Therefore wafer bonding is not a suitable and cost-effective method for some applications.

Another approach is to use Liquid crystal polymer (LCP). It has recently become a popular candidate for various packaging approaches, due to its excellent electrical, mechanical and environmental properties. The material comes in rolls and can be laminated unto the wafer as a film. A general method is to use multiple stacks of LCP. Individual holes were created in a layer of LCP and laminated over the wafer so that the device or FETs are exposed through the holes. This first layer of LCP forms the sidewall of the cavity. Then a second layer of LCP is laminated over the entire wafer, thus enclosing the cavity, see Dane. C. Thompson, Manos M. Tentzeris, John Papapolymerou, “Packaging of MMICs in Multilayer of LCP Substrates,” IEEE Microwave and Wireless Components Letters, vol. 16, No. 7, July 2006. Single stack of LCP can also be used, but cavities still must be formed on the material before lamination unto wafer, see Dane. C. Thompson, Nickolas Kinglsley, Guoan Wang, John Papapolymerou, Manos M. Tentzeris, “RF Characteristics of Thin Film Liquid Crystal Polymer (LCP) Packages for RF MEMS and MMIC Integration”, Microwave Symposium Digest, 2005 IEEE MTT-S International, 12-17 Jun. 2005 Page(s):4 pp. and Mogan Jikang Chen, Anh-Vu H. Pham, Nicole Andrea Evers, Chris Kapusta, Joseph Jannotti, William Kornrumpf, John J. Maciel, Nafiz Karabudak, “Design and Development of a Package Using LCP for RF/Microwave MEMS Switches”, IEEE Transactions on Microwave Theory and Techniques, vol. 54, No. 11, November 2006. The prior work mentioned above involve forming a pattern on the cavity material first and then bonded to the device wafer. There are several disadvantages: First, this is a complicated and cumbersome process. One must ensure very accurate alignment in pattern formation and wafer bond; second, the cavities are generally large that covers the entire chip due to the alignment difficulty. There is not much flexibility in creating cavities that covers just the active devices and individual passive components. Generally, with a larger cavity, not only that the risk for mechanical failure is greater, environmental protection of the package is also compromised, see Aaron Dermarderosian, “Behavior of Moisture in Sealed Electronic Enclosures,” International IMAPS conference in San Diego, October of 2006. These issues with traditional methods limit the manufacturability and performance of the package.

Besides reducing size and cost, a wafer-level package also needs to offer the same level of environmental protection as the traditional packages. They are generally required to pass the leak detection test under Method 1014, MIL-STD-883 and the humidity testing under JEDEC Standard No. 22-A101-B. One way to protect the devices is through the application of hermetic coatings, see M. D. Groner, S. M. George, R. S. McLean and P. F. Carcia, “Gas diffusion barriers on polymers using A12O3 atomic layer deposition,” Applied Physics Letters, 88, 051907 (2006), but direct application of the coating unto certain semiconductor devices can degrade performance.

Another way is to make the package itself hermetic. Wafer bonding methods that fuse silicon or glass together generally can achieve hermetic performance. Plastic packages such as LCP and BCB while capable of passing initial hermeticity tests as defined by MIL-Std 883 Method 1014, are described as near-hermetic due to the diffusion rates through these materials compared to glass and metals, see A. Jourdain, P. De Moor, S. Pamidighantam, H. A. C. Tilmans, “Investigation of the Hermeticity of BCB-Sealed Cavities For Housing RF-MEMS Devices”, IEEE Electronic Article, 2002 and Dane. C. Thompson, Nickolas Kinglsley, Guoan Wang, John Papapolymerou, Manos M. Tentzeris, “RF Characteristics of Thin Film Liquid Crystal Polymer (LCP) Packages for RF MEMS and MMIC Integration”, Microwave Symposium Digest, 2005 IEEE MTT-S International, 12-17 Jun. 2005 Page(s):4 pp

In multichip-module packaging approaches, the chips are packaged by spinning or laminating the dielectric film over the entire chip. Prior work have been done using various combination of Kapton E, BCB, SPIE, etc., seeVikram B. Krishnamurthy, H. S. Cole, T. Sitnik-Nieters, “Use of BCB in High Frequency MCM Interconnects”, IEEE Transactions on Components, Packaging, and Manufacturing Technology—Part B, vol. 19, No. 1, February 1996. Although this reduces the processing complexity but performance is degraded because there is no air cavity over the active devices. A dielectric film deposited directly on top of transistors generally degrades its performance due to the increased parasitic capacitance. The multichip-module packaging is a chip-level rather than a wafer-level approach.

In another wafer-level packaging approach, caps made from different material, such as LCP, glass, etc. were dropped unto the wafer to cover individual chips. The caps were sealed in place using adhesives. Again, this is a complex process that picks and places the caps on individual chips; see George Riley, “Wafer Level Hermetic Cavity Packaging”, http://www.flipchips.com/tutorial43.html

### SUMMARY

In accordance with the present invention, a method is provided for packaging a plurality of semiconductor devices formed in a surface portion of a semiconductor wafer. The method includes: lithographically forming in a material disposed on the surface portion device-exposing openings to expose the devices and electrical contacts pads openings; mounting a rigid dielectric layer over the formed material, such rigid material being suspended over the device exposing openings (i.e., cavities) in the material and over the electrical contacts pads openings in the material.

In one embodiment, the method includes forming electrical contact pad openings in portions of the rigid dielectric layer disposed over electrical contact pads of the devices with other portions of the rigid dielectric layer remaining suspended over the device exposing openings in the material.

In another embodiment, the environmental protection capability of the package can be enhanced by depositing environmentally robust coatings after the application of the rigid material. Thus, the devices can achieve hermetic-like performance but without the cost and complexity of traditional hermetic packages. In addition, performance degradation of the device can be avoided because the coating does not directly coat the device.

Thus, rather than form a pattern on the cavity material first and then bond to the device wafer, a complex and time consuming process having alignment as an issue and where the size of the cavity is generally the size of the entire chip, in accordance with the invention by using a photo-patternable, etchable material cavities are formed unto the wafer using conventional photolithographic techniques. Thus, with such method, a simple and cost-effective way is provided to make wafer-level packages that is environmentally robust and yet maintains optimal circuit performance.

In one embodiment, an additional layer or layers of photoprocessable material and photosensitive epoxy resists (such as Benzocyclobutene (BCB) and SU_{—}8) is formed on either the wafer, the rigid dielectric or both to aid in cavity formation and bonding of the rigid dielectric layer to the lithographically formed on-wafer coating. These coatings may be full or partial cured to aid adhesion at lower lamination pressure and temperature than otherwise required. This protects the semiconductor devices from any potential damage due to high temperature processing and aids in controlling ground/signal spacing, and/or compensates for wafer to dielectric height non-uniformities.

In accordance with another feature of the invention, a package for a semiconductor device formed in a surface portion of a semiconductor wafer is provided. The package includes a lithographically processable, etchable material disposed on the surface portion of the semiconductor wafer having openings therein to expose the device and electrical contacts pads openings therein to expose an electrical contact pad for device and a rigid dielectric layer over the lithographically processable, etchable material, such rigid material being suspended over the device exposing opening in the material.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1 through 10 show a semiconductor wafer having devices therein packaged in accordance with the invention at various steps in such packaging.

Like reference symbols in the various drawings indicate like elements.

### DETAILED DESCRIPTION

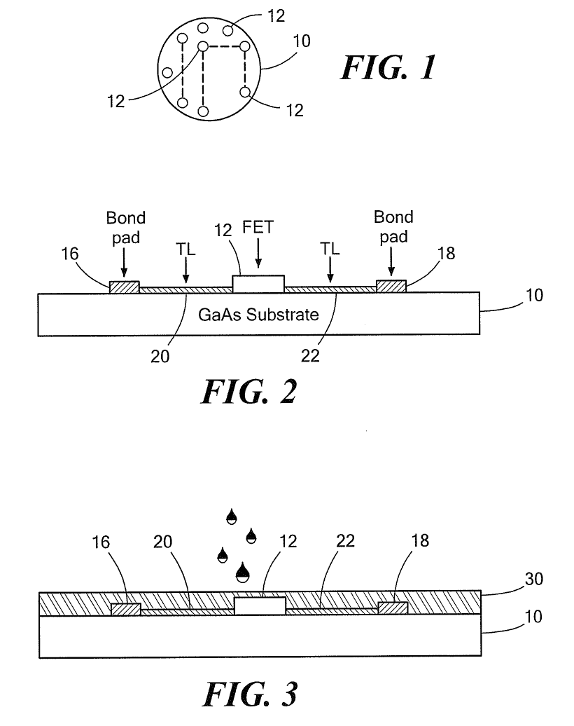

Referring now to FIG. 1, a semiconductor wafer 10 is shown having a plurality of semiconductor devices 12 formed in a surface portion thereof, here the upper surface portion thereof, is shown. An exemplary one of the devices 12 is shown in FIG. 2. Thus, here the wafer is for example, a GaAs wafer 10, and the devices are, for example, field effect transistors (FETs) each one being connected to bond pads 16, 18 through transmission lines 20, 22 respectively, as shown,

Next, a lithographically processable, etchable material 30 is deposited over the upper surface portion of the semiconductor wafer 10, as shown in FIG. 3. Here, for example, lithographically processable, etchable material 30 can be an organic or inorganic material, that can be easily patterned on a wafer using conventional lithographic and etch process to form the sidewall of a cavity to be described. In one embodiment, Benzocyclobutane (BCB) is used being a dielectric material with excellent electrical properties. It has been used in many applications for dielectric coating, 3D interconnect and packaging, see for example, Kenjiro Nishikawa, Suehiro Sugitani, Koh Inoue, Kenji Kamogawa, Tsuneo Tokumitsu, Ichihiko Toyoda, Masayoshi Tanaka, “A Compact V-Band 3-D MMIC Single-Chip Down-Converter Using Photosensitive BCB Dielectric Film”, IEEE Transactions on Microwave Theory and Techniques, vol. 47, No. 12, December 1999, and Rainer Pelzer, Viorel Dragoi, Bart Swinnen, Philippe Soussan, Thorsten Matthias, “Wafer-Scale BCB Resist-Processing Technologies for High Density Integration and Electronic Packaging”, 2005 International Symposium on Electronics Materials and Packaging, December 11-14.

The BCB material 30 can be dispensed as a liquid, spun on, exposed, developed and cured, all using conventional semiconductor fabrication equipment. Because BCB can be patterned by conventional photolithographic technique, it can achieve alignment tolerances and critical dimensions similar to that of photoresist (limited by film thickness). A spin-on process is preferable to a lamination process (such as that for LCP) from a mechanical and process simplicity standpoint. The spin-on process introduces less stress to the wafer, especially for the mechanical fragile structures such as air bridges and is more capable of self leveling over complex circuit topologies.

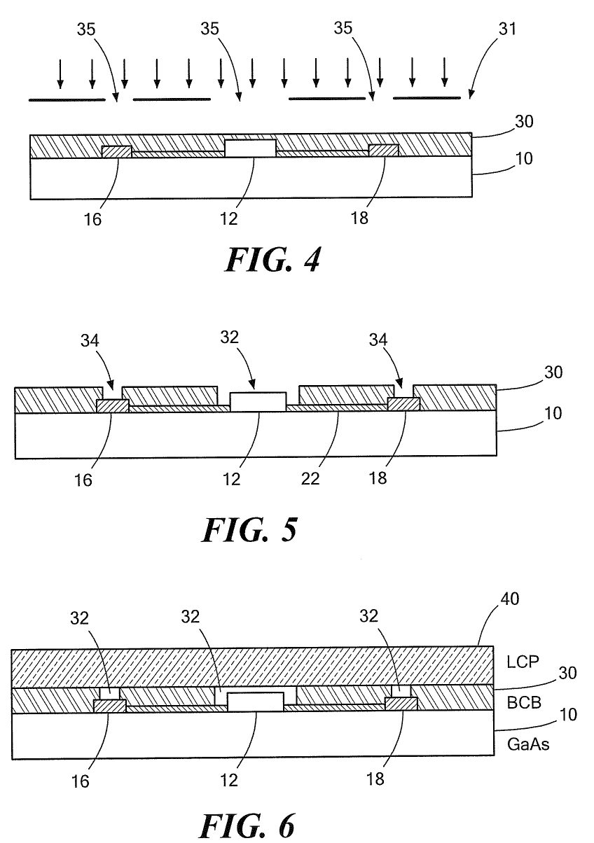

Next, the material 30 is photolithographically processed, as shown in FIG. 4, using a mask 31 having windows 35 disposed over the devices 12 and contact pads 16, 18. After exposed portions of the BCB material 30 are developed away, device openings 32 therein to expose the devices 12 and electrical contacts pads openings 34 therein to expose electrical contact pads 16, 18 as shown in FIG. 5.

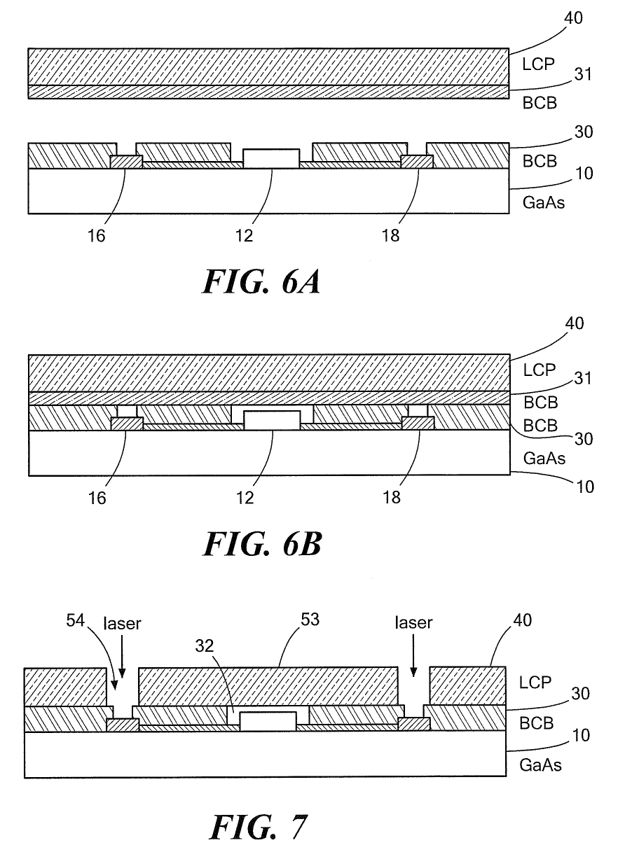

After patterns are formed on the BCB material 30, the openings or cavities 32 are enclosed using a mechanically strong, i.e., rigid self-supporting layer 40 that has good adhesion to BCB material 30. One material for layer 40 is LCP, which can be laminated over the BCB material 30, as shown in FIG. 6. Material 30 should be sufficiently thick so that layer 40 does not directly touch the device 12. The lamination can be done to create either an air or vacuum cavities 32.

If LCP adhesion to BCB is difficult to achieve at a safe processing temperature for the semiconductor device, a thin layer of BCB material 31 as shown in FIGS. 6A and 6B can be spun on the LCP material 40, cured at sufficient temperature to achieve good adhesion and then bonded to the BCB material 30 on the wafer. Generally, it is easier to create adhesion between similar materials than dis-similar materials.

To make electrical connections to the circuit devices 12, laser ablation can be used to remove portions 54 (FIG. 7) of the LCP material 40 and/or BCB material 30 to expose the bond pads 16, 18. Thus, the process forms electrical contact pad openings 32 in portions of the rigid dielectric layer 40 disposed over electrical contact pads 16, 18 of the devices 12 with other portions 53 of the rigid dielectric layer 40 remaining suspended over the device exposing openings 32 in the material 30.

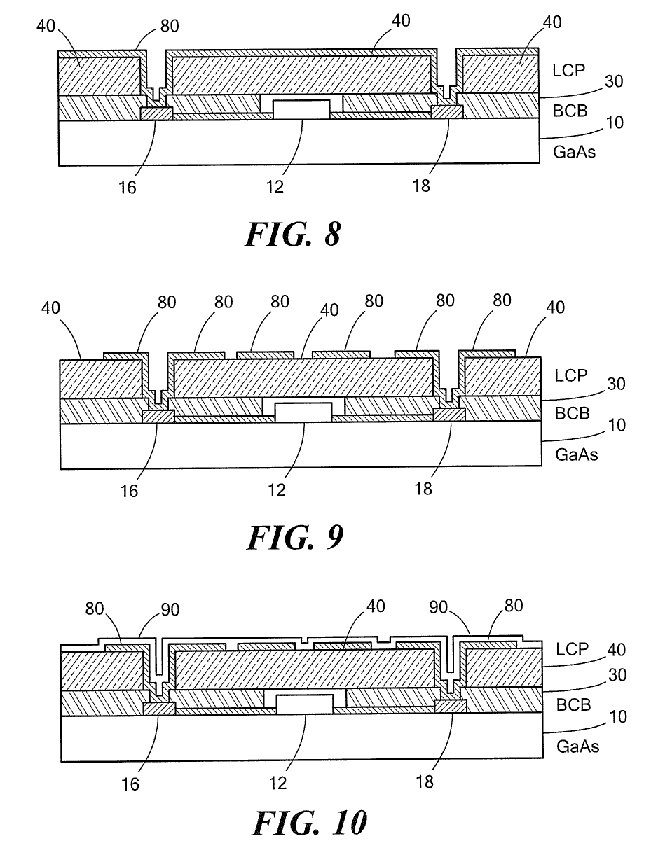

Here, the bond pads 16, 18 can be left exposed for wire bonding as shown in FIG. 7. In addition, metal 80 may be plated over the structure as shown in FIG. 8, such metal 80 being deposited on side walls of the openings formed in layer 40 and material 30 onto the exposed upper portions of the contact pads 16 and 18.

Next, the metal 80 may be patterned for additional contacts or structures, as showing in FIG. 8. Next, environmentally robust coating 90 can be applied and patterned unto the wafer to provide comparable environmental protection to that of hermetic modules, as shown in FIG. 10. Then the process continues in any conventional manner, for example, by thinning the backside of the wafer and dicing the devices into individual; now packaged chips.

A number of embodiments of the invention have been described. For example, materials other than BCB may be used such as SU_{—}8. Nevertheless, it will be understood that various modifications may be made without departing from the spirit and scope of the invention. Accordingly, other embodiments are within the scope of the following claims.

What is claimed is:

1. A method for packaging a plurality of semiconductor devices formed in a surface portion of a semiconductor wafer, such method comprising:
lithographically forming, in a material disposed on the surface portion of the semiconductor wafer, device exposing openings to exposed the devices and electrical contacts pads openings to expose electrical contact pads for devices; and
mounting a rigid dielectric layer over the formed material, such rigid material being suspended over the device exposing openings in the material and over the electrical contacts pads openings in the material;

2. The method recited in claim 1 including forming electrical contact pad openings in portions of the rigid dielectric layer disposed over electrical contact pads of the devices with other portions of the rigid dielectric layer remaining suspended over the device exposing openings in the material.

3. A method for packaging a plurality of semiconductor devices formed in a surface portion of a semiconductor wafer, such method comprising:
depositing a lithographically processable, etchable material over the surface portion of the wafer;
photolithographically forming in the material an opening in a portion of the material over the semiconductor devices and over electrical contacts pads for devices; and
mounting a rigid dielectric layer over the formed material such rigid material being suspended over the openings in the material.

4. The method recited in claim 3 including forming openings in portions of the rigid dielectric layer disposed over electrical contacts of such devices with other portions of the rigid dielectric layer remaining suspended over semiconductor devices.

5. A package for a semiconductor device formed in a surface portion of a semiconductor wafer, comprising:
a lithographically processable, etchable material disposed on the surface portion of the semiconductor wafer having openings therein to exposed the device and electrical contacts pads openings therein to expose an electrical contact pad for device; and
a rigid dielectric layer over the lithographically processable, etchable material, such rigid material being suspended over the device exposing opening in the material.

6. The package recited claim 5, wherein the lithographically processable, etchable material is BCB and the rigid material is a liquid crystal polymer.

7. The method recited claim 1, wherein the lithographically processable etchable material is BCB and the rigid material a liquid crystal polymer.

8. A method for packaging a plurality of semiconductor devices formed in a surface portion of a semiconductor wafer, such method comprising:
depositing a lithographically processable, etchable material over the surface portion of the wafer;
photolithographically forming in the material an opening in a portion of the material over the semiconductor devices and over electrical contacts pads for devices; and
forming a rigid structure having a layer comprising the same material as the lithographically processable, etchable material on a surface of such rigid structure, and mounting the layer of the rigid structure on the lithographically processable, etchable material, such rigid structure being suspended over the openings in the lithographically processable, etchable material.

9. A package for a semiconductor device formed in a surface portion of a semiconductor wafer, comprising:
a lithographically processable, etchable material disposed on the surface portion of the semiconductor wafer having openings therein to exposed the device and electrical contacts pads openings therein to expose an electrical contact pad for device; and
a rigid dielectric structure having a layer comprising the same material as the lithographically processable, etchable material, such layer being disosed on the lithographically processable, etchable material, such rigid material being suspended over the device exposing opening in the material.

10. A method for packaging a plurality of semiconductor devices formed in a surface portion of a semiconductor wafer, such method comprising:
lithographically forming, in a material disposed on the surface portion of the semiconductor wafer, device exposing openings to exposed the devices and electrical contacts pads openings to expose electrical contact pads for devices; and
mounting a self-supporting structure over the formed material, such self-supporting structure being suspended over the device exposing openings in the material and over the electrical contacts pads openings in the material;

11. The method recited in claim 10 including forming electrical contact pad openings in portions of the self-supporting structure disposed over electrical contact pads of the devices with other portions of the self-supporting structure remaining suspended over the device exposing openings in the material.

12. A method for packaging a plurality of semiconductor devices formed in a surface portion of a semiconductor wafer, such method comprising:
depositing a lithographically processable, etchable material over the surface portion of the wafer;
photolithographically forming in the material an opening in a portion of the material over the semiconductor devices and over electrical contacts pads for devices; and
mounting a self-supporting structure over the formed material such self-supporting structure being suspended over the openings in the material.

13. The method recited in claim 12 including forming openings in portions of the self-supporting structure disposed over electrical contacts of such devices with other portions of the self supporting structure remaining suspended over semiconductor devices.

14. A package for a semiconductor device formed in a surface portion of a semiconductor wafer, comprising:
a lithographically processable, etchable material disposed on the surface portion of the semiconductor wafer having openings therein to exposed the device and electrical contacts pads openings therein to expose an electrical contact pad for device; and
a self-supporting structure disposed over the lithographically processable, etchable material, such self-supporting structure being suspended over the device exposing opening in the material.

15. The package recited claim 14, wherein the lithographically processable, etchable material is BCB and the self-supporting structure is a liquid crystal polymer.

16. A method for packaging a plurality of semiconductor devices formed in a surface portion of a semiconductor wafer, such method comprising:
depositing a lithographically processable, etchable material over the surface portion of the wafer;
photolithographically forming in the material an opening in a portion of the material over the semiconductor devices and over electrical contacts pads for devices; and
forming a self-supporting structure having a layer comprising the same material as the lithographically processable, etchable material on a surface of such self-supporting structure, and
mounting the layer of the self-supporting structure on the lithographically processable, etchable material, such self-supporting structure being suspended over the openings in the lithographically processable, etchable material.

17. A package for a semiconductor device formed in a surface portion of a semiconductor wafer, comprising:
a lithographically processable, etchable material disposed on the surface portion of the semiconductor wafer having openings therein to exposed the device and electrical contacts pads openings therein to expose an electrical contact pad for device; and
a self-supporting structure having a layer comprising the same material as the lithographically processable, etchable material, such layer being disosed on the lithographically processable, etchable material, such self-supporting structure being suspended over the device exposing opening in the material.
